(19) United States
(12) Patent Application Publication
(10) Pub. No.: US 2026/0139381 A1
(43) Pub. Date: May 21, 2026

(54) SUBSTRATE PROCESSING METHOD AND SUBSTRATE PROCESSING APPARATUS

(71) Applicant: Tokyo Electron Limited, Tokyo (JP)

(72) Inventor: Ryosuke AKIMOTO, Koshi City (JP)

(73) Assignee: Tokyo Electron Limited, Tokyo (JP)

(21) Appl. No.: 19/390,715

(22) Filed: Nov. 17, 2025

(30) Foreign Application Priority Data
Nov. 18, 2024 (JP) 2024-200594

(51) Int. Cl. C23C 22/05; C23C 22/77; H01L 21/02

(52) U.S. Cl. CPC C23C 22/05; C23C 22/77; H10P 14/6308; H10P 14/69215; H10P 14/69392

(57) ABSTRACT

A substrate processing method includes processing a surface of silicon with an oxidizing aqueous solution containing a hydrogen peroxide solution and an alkaline liquid to form an oxide film on the surface of the silicon, to form a channel region of a transistor; and forming a gate insulating film of the transistor on a surface of the oxide film.

### CROSS-REFERENCE TO RELATED APPLICATION

This application claims priority under 35 U.S.C. § 119(a) to Japanese Patent Application No. 2024-200594 filed on Nov. 18, 2024, the entire disclosure of which are incorporated herein by reference.

### TECHNICAL FIELD

The various aspects and one or more embodiments described herein pertain generally to a substrate processing method and a substrate processing apparatus.

### BACKGROUND

In recent years, a semiconductor device having a transistor featuring a so-called nanosheet structure is under development. In the manufacturing technology for this transistor, a silicon oxide film is formed as an intermediate layer between silicon serving as a channel region and a gate insulating film (see Patent Document 1).
Patent Document 1: Japanese Patent Laid-open Publication No. 2004-111737

### SUMMARY

In one or more embodiments, a substrate processing method includes processing a surface of silicon with an oxidizing aqueous solution containing a hydrogen peroxide solution and an alkaline liquid to form an oxide film on the surface of the silicon, to form a channel region of a transistor; and forming a gate insulating film of the transistor on a surface of the oxide film.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic diagram illustrating a configuration of a substrate processing system according to one or more embodiments;

FIG. 2 is a schematic diagram illustrating an example configuration of a processing device according to one or more embodiments;

FIG. 3 is a perspective view illustrating an example configuration of a transistor according to one or more embodiments;

FIG. 4 is a cross sectional view taken along a line AA of FIG. 3 in the direction indicated by arrows;

FIG. 5 is a flowchart showing a sequence of a manufacturing process for the transistor according to one or more embodiments;

FIG. 6A to FIG. 6D are diagrams for describing the sequence of the manufacturing process for the transistor according to one or more embodiments;

FIG. 7 is a diagram illustrating an example X-ray photoelectron spectroscopy (SPX) spectrum of an oxide film according to one or more embodiments;

FIG. 8 is a diagram showing a relationship between a thickness of the oxide film and a Si⁴⁺ ratio in one or more embodiments and reference examples; and

FIG. 9 is a diagram showing a relationship between a thickness of the oxide film and a Si⁴⁺ ratio in one or more embodiments and reference examples.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, one or more embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of a substrate processing method and a substrate processing apparatus according to the present disclosure will be described in detail with reference to the accompanying drawings. The present disclosure is not limited to one or more embodiments to be described below. Further, it should be noted that the drawings are schematic and relations in sizes of individual components and ratios of the individual components may sometimes be different from actual values. Even between the drawings, there may exist parts having different dimensional relationships or different ratios.

Recently, a semiconductor device equipped with a transistor featuring a so-called nanosheet structure is under development. In the manufacturing technology for this transistor, a silicon oxide film is formed as an intermediate layer between silicon serving as a channel region and a gate insulating film.

However, when using this conventional technology to form the intermediate layer, it is difficult to form a high-quality, thin oxide film, which may lead to deterioration in various characteristics of the manufactured transistor.

In this regard, there has been a demand for development of a technique that can overcome the aforementioned problem and enables production of a transistor featuring enhanced characteristics.

### <Outline of Substrate Processing System>

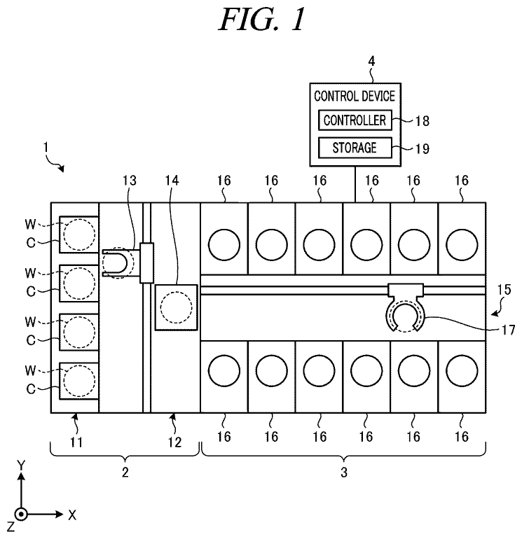

First, a schematic configuration of a substrate processing system 1 according to one or more embodiments will be described with reference to FIG. 1. FIG. 1 is a schematic diagram illustrating a schematic configuration of the substrate processing system 1 according to one or more embodiments. Hereinafter, in order to clarify positional relationships, the X-axis, Y-axis, and Z-axis that are orthogonal to each other will be defined, and the positive Z-axis direction will be regarded as a vertically upward direction.

The substrate processing system 1 is an example of a substrate processing apparatus. As depicted in FIG. 1, the substrate processing system 1 is equipped with a carry-in/out station 2 and a processing station 3. The carry-in/out station 2 and the processing station 3 are provided adjacent to each other.

The carry-in/out station 2 includes a carrier placement section 11 and a transfer section 12. A plurality of carriers C is placed in the carrier placement section 11, and each carrier C accommodates a plurality of substrates (semiconductor wafers W in the present exemplary embodiment) (hereinafter, simply referred to as wafers W) horizontally.

The transfer section 12 is provided adjacent to the carrier placement section 11, and incorporates a substrate transfer device 13 and a delivery module 14. The substrate transfer device 13 is equipped with a wafer holding mechanism configured to hold a wafer W. Also, the substrate transfer device 13 is movable horizontally and vertically and pivotable around a vertical axis, and serves to transfer the wafers W between the carriers C and the delivery module 14 by using the wafer holding mechanism.

The processing station 3 is provided adjacent to the transfer section 12. The processing station 3 is provided with a transfer section 15 and a plurality of processing devices 16. The plurality of processing devices 16 is arranged at both sides of the transfer section 15.

The transfer section 15 is equipped with a substrate transfer device 17 therein. The substrate transfer device 17 is provided with a wafer holding mechanism configured to hold the wafer W. Further, the substrate transfer device 17 is movable horizontally and vertically and pivotable around a vertical axis. The substrate transfer device 17 transfers the wafers W between the delivery module 14 and the processing devices 16 by using the wafer holding mechanism.

The processing devices 16 are each configured to perform a preset processing on the wafer W transferred by the substrate transfer device 17.

Further, the substrate processing system 1 is provided with a control device 4. The control device 4 is, for example, a computer, and includes a controller 18 and a storage 19. The storage 19 stores a program that controls various types of processes performed in the substrate processing system 1. The controller 18 controls the operations of the substrate processing system 1 by reading and executing the program stored in the storage 19. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

Further, the program may have been recorded on a computer-readable recording medium, and may be installed from the recording medium into the storage 19 of the control device 4. The computer-readable recording medium may be, by way of non-limiting example, a hard disc (HD), a flexible disc (FD), a compact disc (CD), a magnet optical disc (MO), a memory card, or the like.

In the substrate processing system 1 configured as described above, the substrate transfer device 13 of the carry-in/out station 2 first takes out the wafer W from the carrier C placed in the carrier placement section 11, and places the taken wafer W in the delivery module 14. The wafer W placed in the delivery module 14 is then taken out from the delivery module 14 by the substrate transfer device 17 of the processing station 3 and carried into the processing device 16.

The wafer W carried into the processing device 16 is processed by the processing device 16, taken out from the processing device 16 by the substrate transfer device 17, and then placed in the delivery module 14. The processed wafer W placed in the delivery module 14 is then transferred by the substrate transfer device 13 to the carrier C in the carrier placement section 11.

### <Configuration of Processing Device>

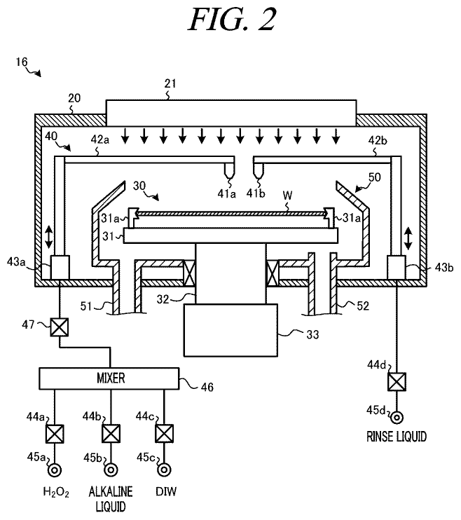

Now, a configuration of the processing device 16 will be explained with reference to FIG. 2. FIG. 2 is a schematic diagram illustrating an example of a specific configuration of the processing device 16 according to one or more embodiments. As depicted in FIG. 2, the processing device 16 includes a chamber 20, a substrate processing module 30, a liquid supply 40, and a recovery cup 50.

The chamber 20 accommodates the substrate processing module 30, the liquid supply 40, and the recovery cup 50. A fan filter unit (FFU) 21 is provided at the ceiling of the chamber 20. The FFU 21 creates a downflow in the chamber 20.

The substrate processing module 30 includes a holder 31, a supporting column 32, and a driver 33, and performs a liquid processing on the placed wafer W. The holder 31 holds the wafer W horizontally. The supporting column 32 is a vertically extending member, with its base end rotatably supported by the driver 33 and its leading end supporting the holder 31 horizontally. The driver 33 rotates the supporting column 32 around a vertical axis.

This substrate processing module 30 rotates the supporting column 32 by using the driver 33, thereby rotating the holder 31 supported by the supporting column 32, and thus allowing the wafer W held by the holder 31 to be rotated.

A holding member 31a is provided on a top surface of the holder 31 of the substrate processing module 30 to hold the wafer W from the side. The wafer W is held horizontally by this holding member 31a, slightly spaced apart from the top surface of the holder 31. Also, the wafer W is held by the holder 31 with its surface to be subjected to a substrate processing facing upwards.

The liquid supply 40 supplies a processing fluid to the wafer W. The liquid supply 40 includes nozzles 41a and 41b, arms 42a and 42b configured to horizontally support the nozzles 41a and 41b, respectively, and pivoting/elevating mechanisms 43a and 43b configured to pivot and elevate the arms 42a and 42b, respectively.

The nozzle 41a is connected to a mixer 46 via a flow rate regulator 47. The mixer 46 is connected to a first source 45a via a flow rate regulator 44a. Also, the mixer 46 is connected to a second source 45b via a flow rate regulator 44b. Further, the mixer 46 is also connected to a third source 45c via a flow rate regulator 44c.

The first source 45a is, byway of example, a tank that stores a hydrogen peroxide solution. The flow rate regulator 44a adjusts the flow rate of the hydrogen peroxide solution supplied to the mixer 46. The flow rate regulator 44a includes an opening/closing valve, a flow rate control valve, a flowmeter, and the like.

The second source 45b is, by way of non-limiting example, a tank that stores a liquid having alkaline properties (hereinafter, simply referred to as “alkaline liquid”). The alkaline liquid in this exemplary embodiment is, for example, ammonia water or a choline solution. The flow rate regulator 44b adjusts the flow rate of the alkaline liquid supplied to the mixer 46. The flow rate regulator 44b includes an opening/closing valve, a flow rate control valve, a flowmeter, and the like.

The third source 45c is, for example, a tank that stores deionized water (DIW). The flow rate regulator 44c adjusts the flow rate of the DIW supplied to the mixer 46. The flow rate regulator 44c includes an opening/closing valve, a flow rate control valve, a flowmeter, and the like.

The mixer 46 mixes the hydrogen peroxide solution supplied from the first source 45a, the alkaline liquid supplied from the second source 45b, and the DIW supplied from the third source 45c to generate an oxidizing aqueous solution having a required concentration of the hydrogen peroxide solution and a required concentration of the alkaline liquid.

The flow rate regulator 47 adjusts the flow rate of the oxidizing aqueous solution supplied from the mixer 46 to the nozzle 41a. The flow rate regulator 47 includes an opening/closing valve, a flow rate control valve, a flowmeter, and the like.

The nozzle 41b is connected to a fourth source 45d via a flow rate regulator 44d. The fourth source 45d is, for example, a tank that stores a rinse liquid. The rinse liquid in one or more embodiments is, by way of example, DIW. However, it should be noted that the rinse liquid in one or more embodiments is not limited to DIW.

The flow rate regulator 44d adjusts the flow rate of the rinse liquid supplied to the nozzle 41b. The flow rate regulator 44d includes an opening/closing valve, a flow rate control valve, a flowmeter, and the like.

The oxidizing aqueous solution supplied from the mixer 46 is discharged from the nozzle 41a. The rinse liquid supplied from the fourth source 45d is discharged from the nozzle 41b.

The recovery cup 50 is positioned to surround the holder 31, and serves to collect a processing liquid scattered from the wafer W due to the rotation of the holder 31. A drain port 51 is formed at a bottom of the recovery cup 50, and the processing liquid collected by the recovery cup 50 is drained to the outside of the processing device 16 through the drain port 51. In addition, an exhaust port 52 is formed at the bottom of the recovery cup 50 to exhaust a gas supplied from the FFU 21 to the outside of the processing device 16.

### <Configuration of Semiconductor Device>

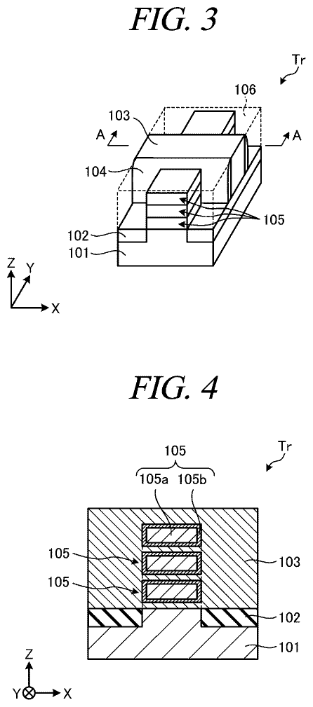

Now, an example configuration of a semiconductor device will be explained with reference to FIG. 3 and FIG. 4. A part of its manufacturing process is performed by the substrate processing system 1 according to one or more embodiments. FIG. 3 is a perspective view showing an example configuration of a transistor Tr according to one or more embodiments. FIG. 4 is a cross sectional view taken along a line A-A in FIG. 3.

As illustrated in FIG. 3 and FIG. 4, the transistor Tr according to one or more embodiments has a so-called nanosheet structure. The transistor Tr according to one or more embodiments includes a semiconductor substrate 101, an insulating film 102, a gate electrode 103, a sidewall insulating film 104, a plurality of nanosheets 105, and an insulating film 106.

The semiconductor substrate 101 is, for example, a silicon substrate. The insulating film 102 is positioned on a surface of the semiconductor substrate 101 and is electrically insulated from an adjacent transistor Tr. The insulating film 102 may be an element isolation film or may be formed as a shallow trench isolation (STI) structure made of an oxide film.

The gate electrode 103 is of, for example, a wall shape, and stands on surfaces of the semiconductor substrate 101 and the insulating film 102. For example, the gate electrode 103 extends along one direction (the X-axis direction in the drawing).

The gate electrode 103 is composed of, by way of non-limiting example, tungsten (W), titanium (Ti), titanium nitride (TiN), hafnium (Hf), hafnium silicide (HfSi), ruthenium (Ru), iridium (Ir), cobalt (Co), or the like.

The sidewall insulating film 104 is positioned to cover a sidewall of the gate electrode 103. The sidewall insulating film 104 is composed of, for example, silicon oxide film (SiO₂), silicon nitride film (SiN), or the like.

The nanosheets 105 are each of, for example, a band shape, and are positioned approximately parallel to the surface of the semiconductor substrate 101. For example, the nanosheets 105 extend along a direction (the Y-axis direction in the drawing) perpendicular to the direction in which the gate electrode 103 extends, penetrating the gate electrode 103.

In the example shown in FIG. 3 and FIG. 4, the number of the stacked nanosheets 105 is, but not limited to, three.

As shown in FIG. 4, the nanosheet 105 includes silicon 105a and a gate insulating film 105b. The silicon 105a serves as a channel region of the transistor Tr inside the gate electrode 103. The gate insulating film 105b is positioned, at least inside the gate electrode 103, so as to cover a surface of the silicon 105a.

Further, a source region of the transistor Tr and a drain region of the transistor Tr are provided at both sides of the nanosheet 105 with the gate electrode 103 therebetween.

The gate insulating film 105b is composed of, by way of non-limiting example, a high-dielectric-constant (high-k) insulating film with a thickness of several nm. The gate insulating film 105b is composed of, for example, hafnium oxide (HfO₂), hafnium silicate (HfSiO), tantalum oxide (Ta₂O₅), hafnium aluminum oxide (HfAlOₓ), or the like.

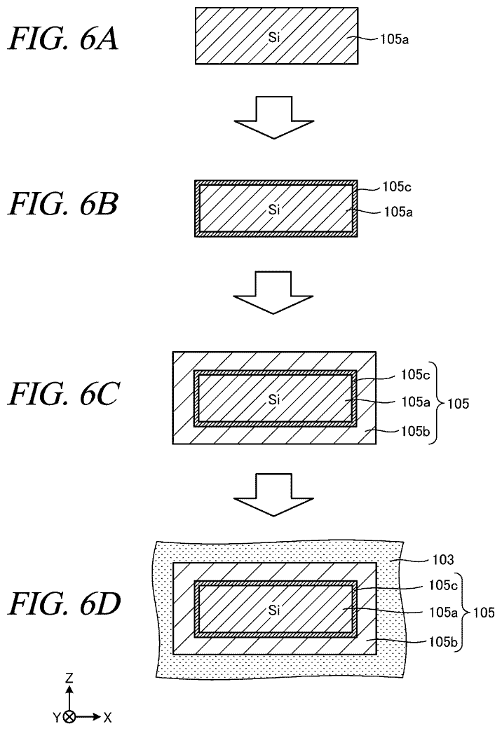

In addition, in the transistor Tr according to one or more embodiments, an oxide film 105c (see FIG. 6A to FIG. 6D) is located between the silicon 105a and the gate insulating film 105b. Details of this oxide film 105c will be described later.

The insulating film 106 is positioned to cover the gate electrode 103 and the plurality of nanosheets 105, and serves to electrically insulate them from an adjacent transistor Tr.

### <Details of Substrate Processing>

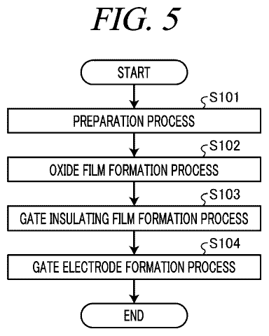

Now, details of the substrate processing for the wafer W in the processing device 16 will be explained with reference to FIG. 5 to FIG. 9. FIG. 5 is a flowchart illustrating a sequence of a manufacturing process for the transistor Tr according to one or more embodiments. FIG. 6A to FIG. 6D are diagrams for describing the sequence of the manufacturing process for the transistor Tr according to one or more embodiments.

As shown in FIG. 5, the substrate processing according to one or more embodiments begins with a preparation process (process S101). In this preparation process, the wafer W (see FIG. 1), on the surface of which the silicon 105a is formed to serve as the channel region of the transistor Tr (see FIG. 4), is prepared, as shown in FIG. 6A.

In the substrate processing according to one or more embodiments, an oxide film formation process is subsequently performed (process S102). In this oxide film formation process, the controller 18 (see FIG. 1) holds the wafer W with the holder 31 (see FIG. 2), and controls the liquid supply 40 (see FIG. 2) and the like to supply the oxidizing aqueous solution from the nozzle 41a (see FIG. 2) to the wafer W being rotated.

As a result, the oxide film 105c is formed on the surface of the silicon 105a, as illustrated in FIG. 6B. Further, after supplying the oxidizing aqueous solution to the wafer W, the controller 18 stops the supply of the oxidizing aqueous solution at an appropriate timing and supplies the rinse liquid from the nozzle 41b. As a result, the oxidizing aqueous solution is removed from the surface of the wafer W, which ends the oxide film formation process.

Furthermore, the controller 18 stops the supply of the rinse liquid from the nozzle 41b (see FIG. 2) and rotates the wafer W at a high speed to shake off the rinse liquid. In this way, a drying process for the wafer W is performed.

In the substrate processing according to one or more embodiments, a gate insulating film formation process is then performed (process S103). In this gate insulating film formation process, the wafer W with the oxide film 105c formed thereon is taken out from the substrate processing system 1 and carried into a film formation device. In this film formation device, the gate insulating film 105b of a required thickness is formed on a surface of the oxide film 105c, as shown in FIG. 6C.

In the substrate processing according to one or more embodiments, a gate electrode formation process is then performed (process S104). In this gate electrode formation process, the gate electrode 103 is formed on a surface of the gate insulating film 105b in a film formation device, as shown in FIG. 6D, which ends the substrate processing according to one or more embodiments.

Here, in one or more embodiments, by processing the surface of the silicon 105a, which becomes the channel region of the transistor Tr, with the oxidizing aqueous solution containing the hydrogen peroxide solution and the alkaline liquid in the oxide film formation process (process S102), it is possible to form the high-quality, thin oxide film 105c.

Since the high-quality oxide film 105c is formed between the silicon 105a and the gate insulating film 105b, a leakage current of the transistor Tr can be reduced.

Furthermore, since the thin oxide film 105c is formed between the silicon 105a and the gate insulating film 105b, the volume of the silicon 105a, which serves as the channel region, can be sufficiently secured even when the transistor Tr is miniaturized.

As stated above, the substrate processing according to one or more embodiments enables the formation of the high-quality, thin oxide film 105c, making it possible to manufacture the transistor Tr with superior characteristics.

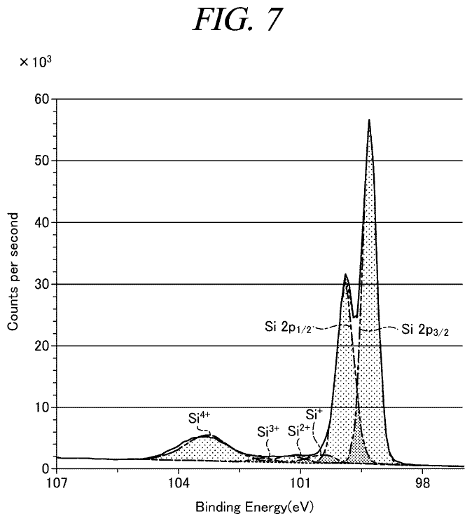

Now, the specific characteristics of the oxide film 105c formed by the oxide film formation process according to one or more embodiments will be explained with reference to FIG. 7 to FIG. 9. FIG. 7 is a diagram illustrating an example X-ray photoelectron spectroscopy (XPS) spectrum of the oxide film 105c according to one or more embodiments.

As depicted in FIG. 7, in the oxide film 105c (see FIG. 6A to FIG. 6D) containing silicon and oxygen, a spectrum with multiple peaks in the binding energy range of 98 eV to 107 eV is obtained by an XPS analysis.

For example, as shown in FIG. 7, a Si 2p_{3/2} peak is observed near the binding energy of 99 eV, and a Si 2p_{1/2} peak is observed near the binding energy of 100 eV. Furthermore, peaks of Si⁺, Si²⁺, Si³⁺, and Si⁴⁺ are observed on the higher energy side than that of the Si 2p_{1/2} peak.

Among these peaks, the Si⁺ peak is attributed to Si₂O in the oxide film 105c, the Si²⁺ peak is attributed to SiO in the oxide film 105c, the Si³⁺ peak is attributed to Si₂O₃ in the oxide film 105c, and the Si⁴⁺ peak is attributed to SiO₂ in the oxide film 105c.

Furthermore, with an increase of a Si⁴⁺ ratio represented by Expression (1) below, the proportion of the SiO₂ in the oxide film 105c becomes higher, so the oxide film 105c may be regarded as having a high quality.

$${Si}^{4 +} ratio = {Si}^{4 +} / \{ {Si}^{+} + S {i}^{2 +} + S {i}^{3 +} + S {i}^{4 +} ) \qquad ( 1 )$$

In the above Expression (1), “Si, Si²⁺,” “Si³⁺,” and “Si⁴⁺” refer to the areas of the Si⁺, Si²⁺, Si³⁺, and Si⁴⁺ peaks, respectively, separated from the XPS spectrum as shown in FIG. 7.

Furthermore, by performing an angle-resolved XPS analysis, a film thickness T of the oxide film 105c can be calculated from the XPS spectrum based on the following Expression (2).

$$\text{?}$$

$$\text{?} \text{indicates text missing or illegible when filed}$$

In the above Expression (2), λ is a given value (3.3 in the case of the XPS analysis), and θ denotes an angle (take-off angle) between a sample surface and a detector. Furthermore, “I_{Si+}”, “I_{Si2+}”, “I_{Si3+}”, and “I_{Si4}+” refer to the intensities of the Si⁺, Si²⁺, Si³⁺, and Si⁴⁺ peaks, respectively, separated from the XPS spectrum as shown in FIG. 7. In addition, “I_{Si2p}” refers to the intensity of the Si 2p_{3/2} peak separated from the XPS spectrum as shown in FIG. 7.

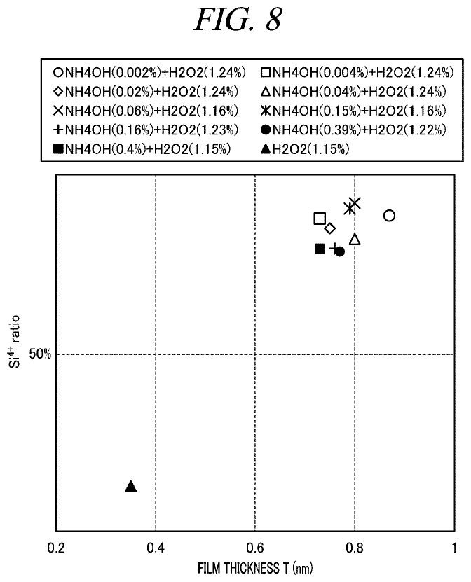

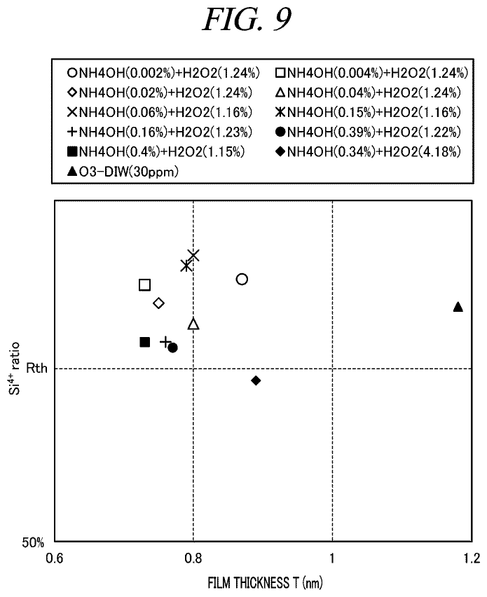

FIG. 8 and FIG. 9 show a relationship between the Si⁴⁺ ratio and the film thickness T of each oxide film 105c formed by using the oxidizing aqueous solution according to one or more embodiments and various processing liquids according to reference examples. FIG. 8 and FIG. 9 are diagrams showing the relationship between the Si⁴⁺ ratio and the film thickness T of each oxide film 105c in one or more embodiments and the reference examples.

As can be seen from FIG. 8, as compared to a sample in which the oxide film 105c is formed by using only the hydrogen peroxide solution, the oxide film 105c with a higher Si⁴⁺ ratio is obtained in a sample in which the oxide film 105c is formed by using the oxidizing aqueous solution prepared by adding the ammonia water, which is an alkaline liquid, to the hydrogen peroxide solution. Here, concentrations of the respective components in the chemical liquids listed in the legends of FIG. 8 and FIG. 9 are all expressed in weight percent (wt %).

In addition, as shown in FIG. 8, the Si⁴⁺ ratios of the oxide films 105c formed by using the oxidizing aqueous solution according to one or more embodiments are all found to be equal to or higher than 50%. That is, in the oxide film 105c formed by using the oxidizing aqueous solution according to one or more embodiments, the SiO₂ content is found to be the highest among the SiO₂, Si₂O, SiO, and Si₂O₃.

The reason for the formation of the high-quality oxide film 105c with the highest SiO₂ content as described above is presumed to be as follows. In the hydrogen peroxide solution, oxidizing species HO₂⁻ is generated by a chemical reaction represented by Expression (3) below.

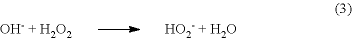

The oxidizing species HO₂⁻ oxidizes silicon in the surface of the silicon 105a, thereby forming the oxide film 105c on the surface of the silicon 105a.

Here, in one or more embodiments, a small amount of the alkaline liquid (e.g., ammonia water) is added to the hydrogen peroxide solution, generating an hydroxide ion OH⁻ through an ionization reaction represented by Expression (4) below.

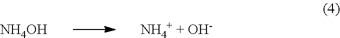

Then, as the hydroxide ion OH⁻ is supplied to the hydrogen peroxide solution, the chemical reaction shown in Expression (3) above is promoted, thus forming the high-quality oxide film 105c.

While the above exemplary embodiment illustrates the example in which the ammonia water is added as the alkaline liquid, the same phenomenon occurs with other alkaline liquids (e.g., a choline solution, etc.).

As shown in FIG. 9, in one or more embodiments, the concentration of the ammonia water contained in the oxidizing aqueous solution may be in the range of 0.0005 wt % to 0.4 wt %. Also, in one or more embodiments, the concentration of the hydrogen peroxide solution contained in the oxidizing aqueous solution may be in the range of 0.005 wt % to 2.0 wt %.

This allows the Si⁴⁺ ratio to be equal to or higher than a given threshold value Rth (>50%), and the film thickness T of the oxide film 105c to be 1.0 nm or less. That is, according to one or more embodiments, it is possible to form the oxide film 105c with a higher quality and a smaller thickness.

Therefore, according to one or more embodiments, the transistor Tr with an even better characteristics can be formed.

Further, in FIG. 9, as a reference example, data of the oxide film 105c formed by using 30 ppm of ozone water (referred to as “03-DIW”) is also presented. However, it is apparent that the oxide film 105c with a thinner thickness is formed by using the oxidizing aqueous solution according to one or more embodiments.

Furthermore, in one or more embodiments, the film thickness T of the oxide film 105c may be in the range of 0.6 nm to 1.0 nm.

By setting the film thickness T of the oxide film 105c to 0.6 nm or more, the leakage current of the transistor Tr can be reduced. Furthermore, by setting the film thickness T of the oxide film 105c to 1.0 nm or less, a sufficient volume of the silicon 105a that forms the channel region can be ensured even when the transistor Tr is miniaturized.

In addition, in one or more embodiments, the temperature of the oxidizing aqueous solution in the oxide film formation process (process S102) may be between 20° C. and 70° C. inclusive.

By setting the temperature of the oxidizing aqueous solution to 20° C. or higher, the oxide film 105c can be efficiently produced. Furthermore, by setting the temperature of the oxidizing aqueous solution to 70° C. or lower, an excessive oxidation reaction can be suppressed, thereby enabling the stable production of the oxide film 105c with the small film thickness T.

In addition, the gate insulating film 105b formed on the surface of the oxide film 105c in this exemplary embodiment may include hafnium oxide as a main component. This further reduces the leakage current of the transistor Tr.

The substrate processing method according to one or more embodiments includes the process of forming the oxide film 105c (process S102) and the process of forming the gate insulating film 105b (process S103). In the process of forming the oxide film 105c (process S102), the surface of the silicon 105a that will serve as the channel region of the transistor Tr is treated with the oxidizing aqueous solution containing the hydrogen peroxide solution and the alkaline liquid to form the oxide film 105c on the surface of the silicon 105a. In the process of forming the gate insulating film 105b (process S103), the gate insulating film 105b of the transistor Tr is formed on the surface of the oxide film 105c. As a result, it is possible to form the transistor Tr with superior characteristics.

Furthermore, in the substrate processing method according to one or more embodiments, the oxidizing aqueous solution contains the hydrogen peroxide solution and the ammonia water. This allows for the manufacture of the transistor Tr with superior characteristics.

Furthermore, in the substrate processing method according to one or more embodiments, the concentration of the ammonia water contained in the oxidizing aqueous solution is in the range of 0.0005 wt % to 0.4 wt %. This enables a manufacture of the transistor Tr with even better characteristics.

Moreover, in the substrate processing method according to one or more embodiments, the concentration of the hydrogen peroxide solution contained in the oxidizing aqueous solution is in the range of 0.005 wt % to 2.0 wt %. This allows for the manufacture of the transistor Tr with even better characteristics.

Besides, in the substrate processing method according to one or more embodiments, the temperature of the oxidizing aqueous solution is in the range of 20° C. to 70° C. This enables efficient production of the oxide film 105c, and also allows for stable production of the oxide film 105c with the small film thickness T.

In addition, in the substrate processing method according to one or more embodiments, the oxide film 105c includes at least one of SiO₂, Si₂O, SiO, and Si₂O₃, and the content of the SiO₂ is the highest in the oxide film 105c. Therefore, the transistor Tr with superior characteristics can be manufactured.

Further, in the substrate processing method according to one or more embodiments, the thickness T of the oxide film 105c is in the range of 0.6 nm to 1.0 nm. This allows for the reduction of the leakage current of the transistor Tr, and also ensures a sufficient volume of the silicon 105a serving as the channel region even when the transistor Tr is miniaturized.

Furthermore, in the substrate processing method according to one or more embodiments, the gate insulating film 105b is primarily composed of hafnium oxide. This enables further reduction of the leakage current of the transistor Tr.

The substrate processing apparatus (substrate processing system 1) according to one or more embodiments includes the holder 31, the liquid supply 40, and the controller 18. The holder 31 holds and rotates the substrate (wafer W) on which the silicon 105a, which will serve as the channel region of the transistor Tr, is formed. The liquid supply 40 supplies the oxidizing aqueous solution containing the hydrogen peroxide solution and the alkaline liquid to the substrate (wafer W) held by the holder 31. The controller 18 controls the individual components. The controller 18 also processes the surface of the silicon 105a formed on the substrate (wafer W) with the oxidizing aqueous solution to form the oxide film 105c on the surface of the silicon 105a before the gate insulating film 105b of the transistor Tr is formed. Thus, the transistor Tr with superior characteristics can be manufactured.

So far, one or more embodiments of the present disclosure have been described. However, the present disclosure is not limited to the above exemplary embodiments, and various changes and modifications may be made without departing from the spirit of the present disclosure. For example, while the above exemplary embodiments have been described for the example where the technology of the present disclosure is applied to the transistor Tr with the nanosheet structure, the present disclosure is not limited thereto.

By way of example, the technology of the present disclosure may be applied to transistors of various types, such as a planar structure, a FinFET structure, or a nanowire structure. In such cases as well, since the oxide film 105c of a high quality and a thin thickness can be formed between the silicon 105a and the gate insulating film 105b, a transistor with superior characteristics can be manufactured.

It should be noted that the above-described exemplary embodiment is illustrative in all aspects and is not anyway limiting. In fact, the above-described exemplary embodiment can be embodied in various forms. The above-described exemplary embodiment may be omitted, replaced and modified in various ways without departing from the scope and the spirit of claims.

According to one or more embodiments, it is possible to manufacture the transistor with superior characteristics. It should be noted that the effects described herein are not necessarily limiting, and any of the effects described in the present disclosure may be applicable.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of one or more embodiments. It shall be understood that all modifications and embodiments conceived from the meaning and scope of the claims and their equivalents are included in the scope of the inventive concept. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

We claim:

1. A substrate processing method, comprising:
processing a surface of silicon with an oxidizing aqueous solution containing a hydrogen peroxide solution and an alkaline liquid to form an oxide film on the surface of the silicon, to form a channel region of a transistor; and
forming a gate insulating film of the transistor on a surface of the oxide film.

2. The substrate processing method of claim 1,
wherein the oxidizing aqueous solution contains the hydrogen peroxide solution and ammonia water.

3. The substrate processing method of claim 2,
wherein the ammonia water contained in the oxidizing aqueous solution has a concentration of 0.0005 wt % to 0.4 wt %.

4. The substrate processing method of claim 1,
wherein the hydrogen peroxide solution contained in the oxidizing aqueous solution has a concentration of 0.005 wt % to 2.0 wt %.

5. The substrate processing method of claim 1,
wherein during the processing of the silicon, the oxidizing aqueous solution has a temperature of 20° C. to 70° C.

6. The substrate processing method of claim 1,
wherein the oxide film contains at least one of SiO₂, Si₂O, SiO, or Si₂O₃, and a content ratio of the SiO₂ is the highest in the oxide film.

7. The substrate processing method of claim 1,
wherein the oxide film has a film thickness of 0.6 nm to 1.0 nm.

8. The substrate processing method of claim 1,
wherein the gate insulating film is composed of hafnium oxide as a main component.

9. A substrate processing apparatus, comprising:
a holder to hold and rotate a substrate on which silicon, which is to serve as a channel region of a transistor, is formed;
a liquid supply to supply an oxidizing aqueous solution containing a hydrogen peroxide solution and an alkaline liquid to the substrate held by the holder; and
control circuitry configured to control the holder and the liquid supply to process a surface of the silicon formed on the substrate with the oxidizing aqueous solution to form an oxide film on the surface of the silicon before a gate insulating film of the transistor is formed.

10. The substrate processing apparatus of claim 9,
wherein the oxidizing aqueous solution contains the hydrogen peroxide solution and ammonia water.

11. The substrate processing apparatus of claim 10,
wherein the ammonia water contained in the oxidizing aqueous solution has a concentration of 0.0005 wt % to 0.4 wt %.

12. The substrate processing apparatus of claim 9,
wherein the hydrogen peroxide solution contained in the oxidizing aqueous solution has a concentration of 0.005 wt % to 2.0 wt %.

13. The substrate processing apparatus of claim 9,
wherein during the processing of the silicon, the oxidizing aqueous solution has a temperature of 20° C. to 70° C.

14. The substrate processing apparatus of claim 9,
wherein the oxide film contains at least one of SiO₂, Si₂O, SiO, or Si₂O₃, and a content ratio of the SiO₂ is the highest in the oxide film.

15. The substrate processing apparatus of claim 9,
wherein the oxide film has a film thickness of 0.6 nm to 1.0 nm.

16. The substrate processing apparatus of claim 9,
wherein the gate insulating film is composed of hafnium oxide as a main component.

17. A non-transitory computer-readable medium storing instructions that, when executed by a processor, cause the processor to perform operations comprising:
controlling a holder to hold and rotate a substrate on which silicon, which is to serve as a channel region of a transistor, is formed;
controlling a liquid supply to supply an oxidizing aqueous solution containing a hydrogen peroxide solution and an alkaline liquid to the substrate to process a surface of the silicon and form an oxide film on the surface of the silicon; and
forming a gate insulating film of the transistor on a surface of the oxide film.

18. The non-transitory computer-readable medium of claim 17, wherein the operations further comprise controlling the liquid supply to mix the hydrogen peroxide solution and ammonia water to generate the oxidizing aqueous solution.

19. The non-transitory computer-readable medium of claim 18, wherein the operations further comprise adjusting a concentration of the ammonia water in the oxidizing aqueous solution to be in a range of 0.0005 wt % to 0.4 wt %.

20. The non-transitory computer-readable medium of claim 17, wherein the operations further comprise adjusting a concentration of the hydrogen peroxide solution in the oxidizing aqueous solution to be in a range of 0.005 wt % to 2.0 wt %.
